(19) United States
(12) Patent Application Publication
(10) Pub. No.: US 2014/0069480 A1
(43) Pub. Date: Mar. 13, 2014

(54) PHOTOVOLTAIC MODULE, PHOTOVOLTAIC SYSTEM, AND LIGHT ADMITTING APPARATUS

(71) Applicant: Sano Sano, (US)

(72) Inventor: Yoshihiko Sano, Osaka (JP)

(21) Appl. No.: 14/113,013

(22) PCT Filed: May 24, 2012
(86) PCT No.: PCT/JP2012/063361

§ 371 Date: Nov. 20, 2013

(30) Foreign Application Priority Data
May 24, 2011 (JP) 2011-115886
Dec. 21, 2011 (JP) 2011-280157

(51) Int. Cl. H01L 31/042; H01L 31/02

(52) U.S. Cl. CPC H01L 31/042; H01L 31/02
USPC 136/244; 136/256

(57) ABSTRACT

Disclosed is a photovoltaic module with a bar-like external shape. The photovoltaic module includes a main body section giving the bar-like external shape, a photovoltaic element provided inside the main body section, and output terminals formed at respective ends of the main body section for output of electric power generated by the photovoltaic element. The main body section is covered with a transparent synthetic resin film.

### TECHNICAL FIELD

The present invention relates to a photovoltaic module with a bar-like external shape, a photovoltaic system including a plurality of photovoltaic modules, and a light admitting apparatus including a photovoltaic system.

### BACKGROUND ART

Solar cells (photovoltaic systems) of various shapes have been proposed for improved power generation efficiency to respond to increasing interest in clean energy. The most popularly used ones are those with a planar light receiving face for sunlight. Solar cells with light receiving faces arranged in a cylindrical (columnar) form (as opposed to planar light receiving faces) have also been proposed for improved power generation cost (see, for example, Patent Documents 1 and 2).

An exemplary conventional photovoltaic system will be described in reference to FIGS. 10A and 10B.

FIG. 10A is an oblique view of an arrangement of solar cell modules in a conventional photovoltaic system.

FIG. 10B is a side view of the photovoltaic system shown in FIG. 10A as viewed from the lengthwise direction (arrangement direction) of the solar cell modules.

The photovoltaic system 101 includes a plurality of cylindrical solar cell modules 112 each extending in arrangement direction Df (lengthwise direction) in a plane. The solar cell modules 112 are supported by holders 115 at both ends. Sunlight, identified as illumination light LS, changes its direction with time. However, since sunlight moves along the cylinder's circumference, and the light receiving condition of the solar cell modules 112 remains substantially unchanged, relatively stable solar electric generation is possible. The solar cell modules 112 are separated from each other by suitable intervals so that they can receive sunlight equally even when the sun is not shining directly from above.

The solar cell modules 112 are elevated to a height above an installation surface RF by an installation member 140 so as to receive sunlight. A reflection member RB is provided on the installation surface RF to produce reflection (scattered light) which hits the non-illumination light side (backside) of the solar cell modules 112. The reflection member RB is formed of, for example, white paint.

The solar cell module (photovoltaic module) 112 is typically made of a glass tube, and if installed outdoors, can be damaged due to a mechanical impact from the surroundings and may produce scattered glass fragments. There is also a demand to modify the photovoltaic system 101 including the solar cell modules 112 so that it is more broadly applicable.

### CITATION LIST

### Patent Literature

Patent Document 1: Published Japanese Translation of PCT Application, Tokuhyo, No. 2010-529641
Patent Document 2: Published Japanese Translation of PCT Application, Tokuhyo, No. 2010-541205

### SUMMARY OF THE INVENTION

### Technical Problem

As mentioned above, the photovoltaic system 101 requires the provision of the reflection member RB to produce reflection which hits the non-illumination light side of the solar cell modules 112. In addition, no power generation occurs in the intervals between the solar cell modules 112, which is a cause of limitation in improvement of power generation capability per unit area. A further issue is the need to ensure safety when the solar cell module 112 is damaged.

The present invention, conceived in view of these problems, has an object to provide a photovoltaic module capable of ensuring safety when damaged, by providing a transparent synthetic resin film around a bar-like photovoltaic module.

The present invention has another object to provide a photovoltaic system capable of improving the power generation capability per unit area of groups of two-dimensionally arranged bar-like photovoltaic modules disposed where illumination light is shone, by overlapping the groups of photovoltaic modules parallel to each other.

The present invention has a further object to provide a light admitting apparatus capable of admitting light by applying the photovoltaic modules in accordance with the present invention.

### Solution to Problem

A photovoltaic module in accordance with the present invention is a photovoltaic module with a bar-like external shape, the module including: a main body section forming the external shape; a photovoltaic element provided inside the main body section; and output terminals provided on respective ends of the main body section for output of electric power generated by the photovoltaic element, wherein the main body section is covered with a transparent synthetic resin film.

According to the configuration, the photovoltaic module in accordance with the present invention has a main body section with a bar-like external shape covered with a transparent synthetic resin film. Therefore, the transparent synthetic resin film covering the glass tube restrains glass fragments from scattering and ensures safety if, for example, the main body section is made of a member which can break like a glass tube and damaged by any chance.

A photovoltaic system in accordance with the present invention is a photovoltaic system, including: a first group of photovoltaic modules prepared by two-dimensionally arranging the photovoltaic modules in accordance with the present invention with intervals therebetween; and first holders for holding the first group of photovoltaic modules.

According to the configuration, the photovoltaic system in accordance with the present invention includes: a first group of photovoltaic modules prepared by two-dimensionally arranging the photovoltaic modules in accordance with the present invention with intervals therebetween; and first holders for holding the first group of photovoltaic modules. Therefore, solar electric generation is realized which is very safe and efficient.

A light admitting apparatus in accordance with the present invention is a light admitting apparatus including: a photovoltaic system in accordance with the present invention including a plurality of photovoltaic modules with a bar-like external shape; and a support section for supporting the photovoltaic system.

According to the configuration, the light admitting apparatus in accordance with the present invention both generates electricity from solar energy and admits light, which adds to the usage of the photovoltaic modules.

### Advantageous Effects of the Invention

According to the photovoltaic module in accordance with the present invention, the transparent synthetic resin film covering the glass tube restrains glass fragments from scattering and ensures safety if, for example, the main body section is made of a member which can break like a glass tube and damaged by any chance.

According to the photovoltaic system in accordance with the present invention, solar electricity generation is realized which is very safe and efficient.

The light admitting apparatus in accordance with the present invention both generates electricity from solar energy and admits light, which adds to the usage of the photovoltaic modules.

### BRIEF DESCRIPTION OF DRAWINGS

FIG. 1A is a schematic cross-sectional view of an internal structure of a photovoltaic module in accordance with embodiment 1 of the present invention.

FIG. 1B is a cross-sectional view of a variation of the photovoltaic module shown in FIG. 1A where the extent of coverage provided by a transparent synthetic resin film is modified.

FIG. 2A is an exploded perspective view of a first group of photovoltaic modules and a second group of photovoltaic modules which together constitute a photovoltaic system in accordance with embodiment 2 of the present invention, with the first and second groups being shown detached from each other.

FIG. 2B is a side view of the photovoltaic system shown in FIG. 2A as viewed from the lengthwise direction (arrangement direction) of the first group of photovoltaic modules.

FIG. 2C is a plan view of the photovoltaic system shown in FIG. 2B as viewed from an illumination light side.

FIG. 3A is an exploded perspective view of a first group of photovoltaic modules and a second group of photovoltaic modules which together constitute a photovoltaic system in accordance with embodiment 3 of the present invention, with the first and second groups being shown detached from each other.

FIG. 3B is a side view of the photovoltaic system shown in FIG. 3A as viewed from the lengthwise direction (arrangement direction) of the first group of photovoltaic modules.

FIG. 3C is a plan view of the photovoltaic system shown in FIG. 3B as viewed from an illumination light side.

FIG. 4 is a side view of a photovoltaic system in accordance with embodiment 4 of the present invention, showing a gap between a first group of photovoltaic modules and a second group of photovoltaic modules which together constitute the photovoltaic system.

FIG. 5 is a side view of a photovoltaic system in accordance with embodiment 5 of the present invention, showing relative positions of a first group of photovoltaic modules, a second group of photovoltaic modules, and a third group of photovoltaic modules which together constitute the photovoltaic system.

FIG. 6 is a schematic cross-sectional partial view of first holders connecting photovoltaic modules in accordance with embodiment 6 of the present invention.

FIG. 7 is a schematic cross-sectional view of an internal structure of the photovoltaic modules shown in FIG. 6.

FIG. 8A is a schematic and conceptual oblique view of a light admitting apparatus (example 1) in accordance with embodiment 7 of the present invention.

FIG. 8B is a schematic and conceptual oblique view of a light admitting apparatus (example 2) in accordance with embodiment 7 of the present invention.

FIG. 8C is a schematic and conceptual oblique view of a light admitting apparatus (example 3) in accordance with embodiment 7 of the present invention.

FIG. 8D is a schematic and conceptual oblique view of a light admitting apparatus (example 4) in accordance with embodiment 7 of the present invention.

FIG. 9A is a graph representing how light admittance changes in relation to the path of the sun (altitude and direction) and the arrangement of photovoltaic modules ((module diameter):(module interval)=1:1).

FIG. 9B is a graph representing how a light admittance changes in relation to the path of the sun (altitude and direction) and the arrangement of photovoltaic modules ((module diameter):(module interval)=1:1.6).

FIG. 10A is an oblique view of an arrangement of solar cell modules in a conventional photovoltaic system.

FIG. 10B is a side view of the photovoltaic system shown in FIG. 10A as viewed from the lengthwise direction (arrangement direction) of the solar cell modules.

### DESCRIPTION OF EMBODIMENTS

The following will describe embodiments of the present invention in reference to drawings.

### Embodiment 1

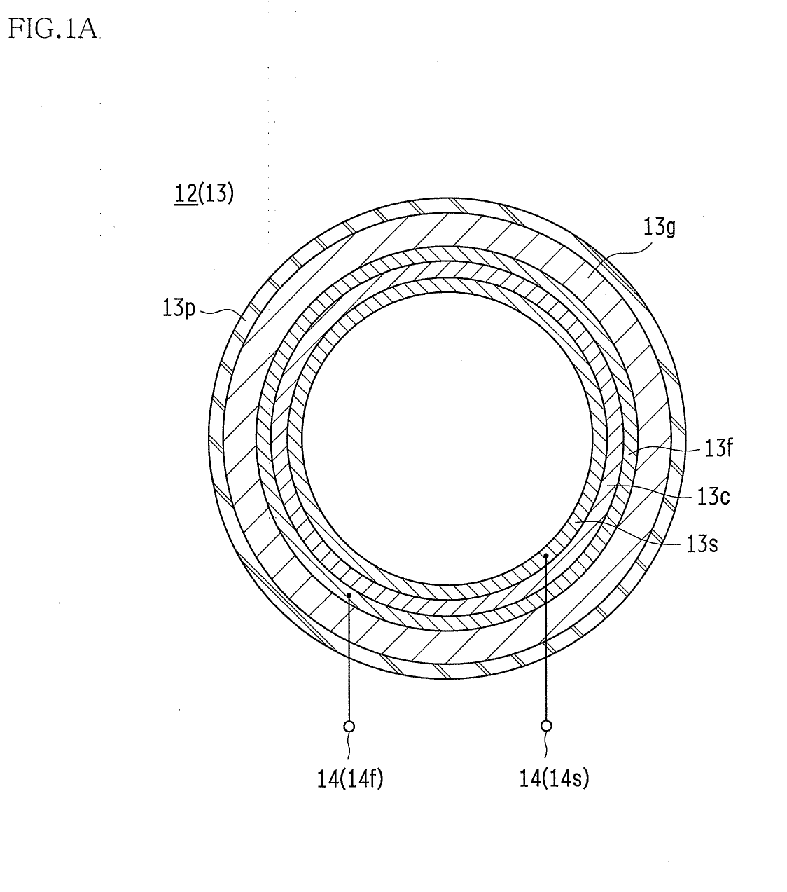

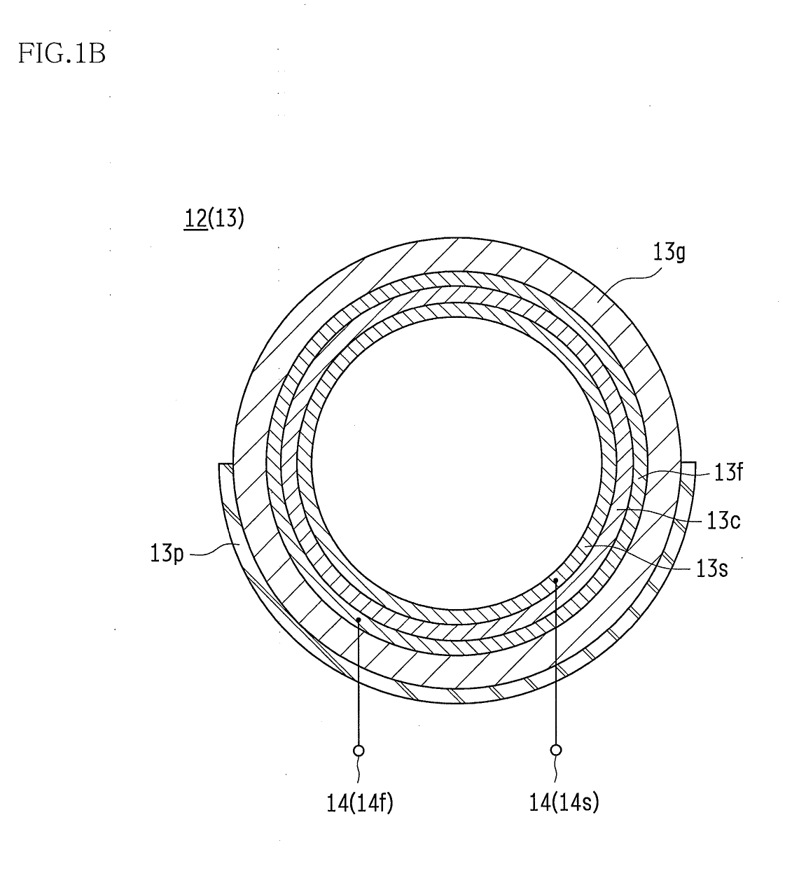

FIG. 1A is a schematic cross-sectional view of an internal structure of a photovoltaic module 12 in accordance with embodiment 1 of the present invention.

FIG. 1B is a cross-sectional view of a variation of the photovoltaic module 12 shown in FIG. 1A where the extent of coverage provided by a transparent synthetic resin film 13p is modified.

The photovoltaic module 12 (main body section 13) in accordance with the present embodiment has a bar-like external shape and includes a photovoltaic element (e.g., solar cell element) provided inside the bar-shaped exterior. Specifically, the photovoltaic module 12 includes the main body section 13 and output terminals 14 provided on the ends of the main body section 13. The output terminals 14 consists of an output terminal 14f corresponding to an outer electrode 13f and an output terminal 14s corresponding to an inner electrode 13s.

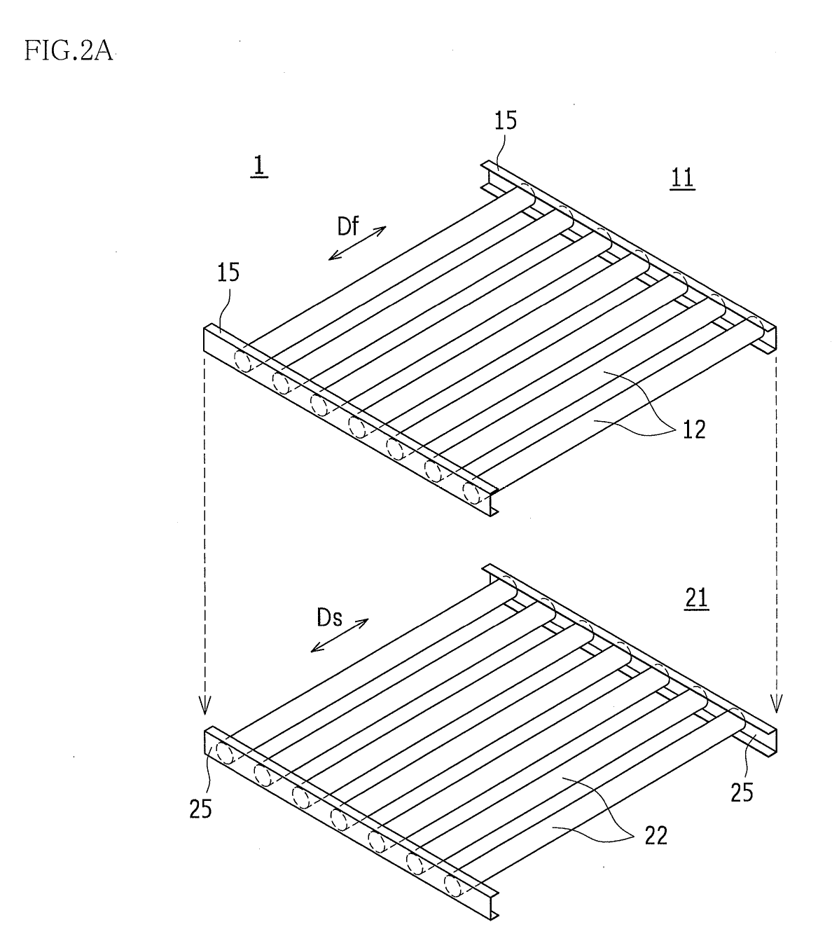

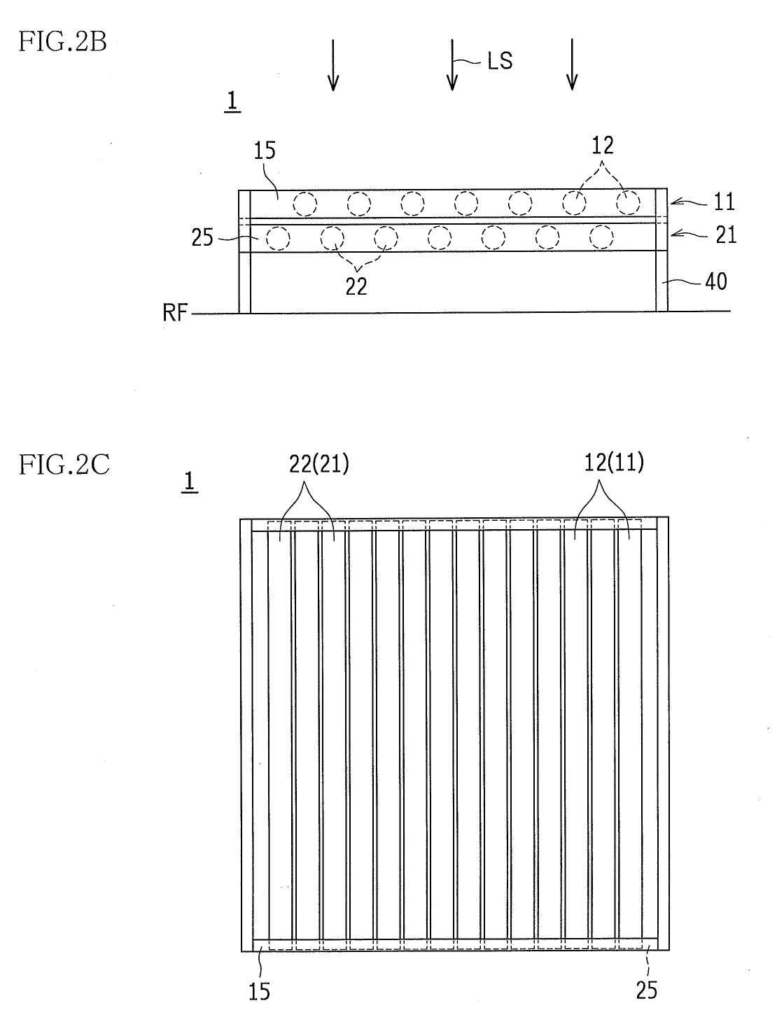

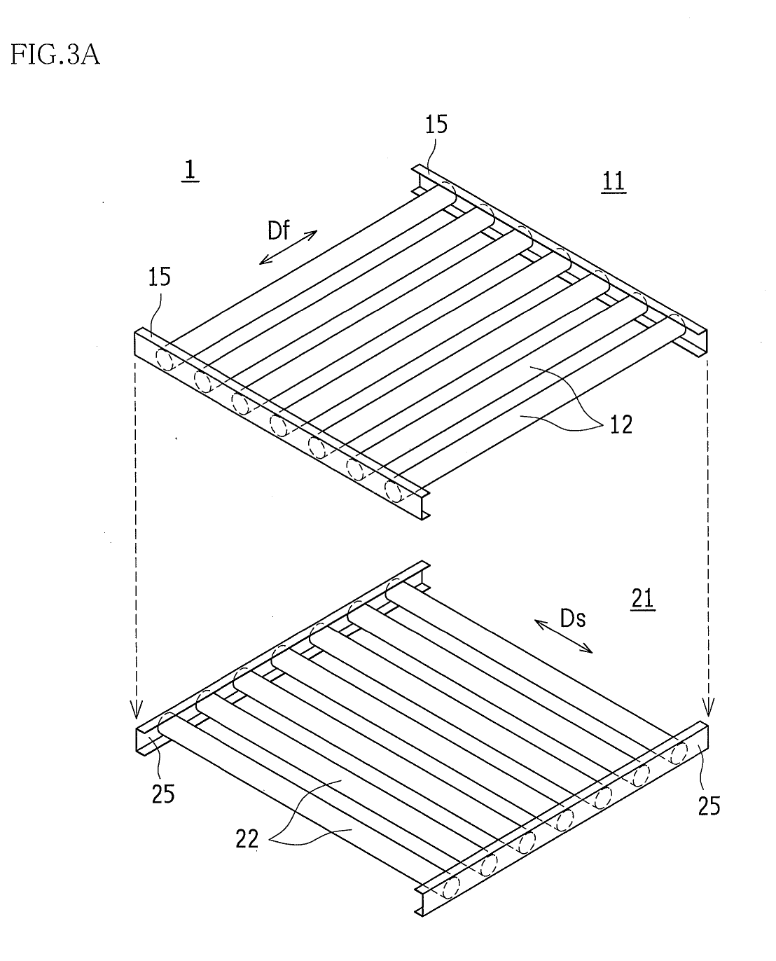

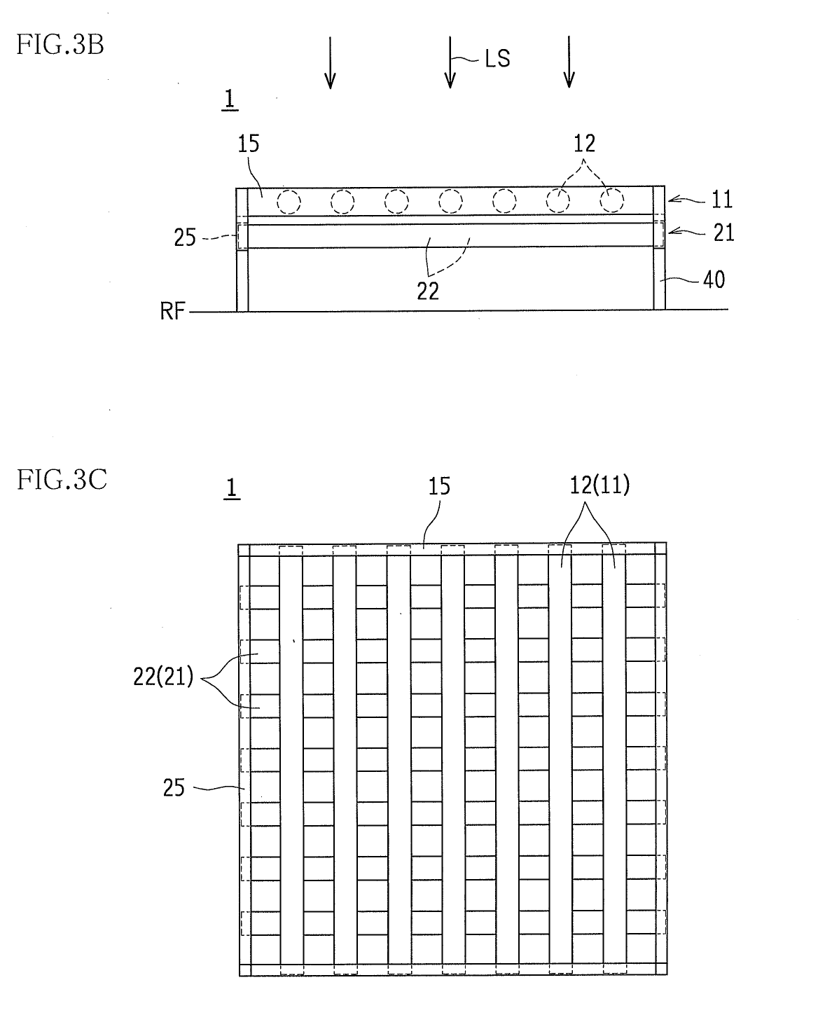

The main body section 13 is transparent so that it can admit external illumination light LS (see FIGS. 2B and 3B) and made of, for example, a cylindrical glass tube. The main body section 13 is preferably cylindrical in order to ensure strength and also to allow sufficient illumination light to uniformly illuminate the bar-like interior, in no matter which direction the illumination light LS is traveling. The cylinder has a diameter (outer circumference) of, for example, approximately 20 mm to 40 mm and a length of, for example, approximately 1,000 mm. The cylinder has a sufficient thickness to ensure strength, for example, approximately 1 mm.

The photovoltaic module 12 includes a glass tube 13g constituting the main body section 13, an outer electrode 13f disposed inside the glass tube 13g, a photoelectric conversion layer (photovoltaic layer) 13c disposed inside the outer electrode 13f, and an inner electrode 13s disposed inside the photoelectric conversion layer 13c. A photovoltaic element is formed by the outer electrode 13f, the photoelectric conversion layer 13c, and the inner electrode 13s.

The main body section 13 is covered with the transparent synthetic resin film 13p. The provision of the transparent synthetic resin film 13p reinforces the strength of the main body section 13 (glass tube 13g) and restrains the glass tube 13g from breaking into fragments and scattering. The transparent synthetic resin film 13p preferably covers all around the glass tube 13g. The transparent synthetic resin film 13p, formed all around the glass tube 13g, unfailingly protects the glass tube 13g. The transparent synthetic resin film 13p preferably covers at least a half of the glass tube 13g which faces the ground as shown in FIG. 1B. The transparent synthetic resin film 13p, formed to cover a half of the glass tube 13g which faces the ground, can be a precaution against falling and other undesirable events.

The main body section 13 is by no means limited to a glass tube and may be made of another transparent raw material, for example, an acrylic resin or other plastic, a ceramic, or a like material. If the main body section 13 is a glass tube 13g, the main body section 13 is preferably covered with a transparent synthetic resin film 13p.

As mentioned above, the photovoltaic module 12 in accordance with the present embodiment has a bar-like external shape and includes the main body section 13 (e.g., glass tube 13g) forming the external shape, the photovoltaic element (the outer electrode 13f, the photoelectric conversion layer 13c, and the inner electrode 13s) provided inside the main body section 13, and the output terminals 14 formed on the respective ends of the main body section 13 for output of electric power generated by the photovoltaic element. The main body section 13 is covered with the transparent synthetic resin film 13p.

According to the photovoltaic module 12 in accordance with the present embodiment, the main body section 13 with a bar-like external shape is covered with the transparent synthetic resin film 13p. Therefore, the transparent synthetic resin film 13p covering the glass tube 13g restrains glass fragments from scattering and ensures safety if for example, the main body section 13 is made of a member which can break like a glass tube 13g and damaged by any chance.

Specifically, the transparent synthetic resin film 13p is preferably a fluorine-based resin film. An alternative may be an ionomer film (IO film), a polyethylene film (PE film), a polyvinyl chloride film (PVC film), a polyvinylidene chloride film (PVDC film), a polyvinyl alcohol film (PVA film), a polypropylene film (PP film), a polyester film, a polycarbonate film (PC film), a polyacrylonitrile film (PAN film), an ethylene-vinyl alcohol copolymer film (EVOH film), an ethylene-methacrylic acid copolymer film (EMAA film), a nylon film (NY film, polyamide (PA) film), or cellophane.

As a further alternative, the transparent synthetic resin film 13p may be made of a photocatalytic coating material (titanium oxide photocatalytic layer). The transparent synthetic resin film 13p, made of a photocatalytic coating material, will likely keep itself free of dirt which would otherwise degrade the properties of the transparent synthetic resin film 13p.

An adhesive for use in applying the transparent synthetic resin film 13p to the main body section 13 (glass tube 13g) may be, for example, of a pressure sensitive, transparent type. The pressure sensitive adhesive preferably contains a UV light absorbent. The use of a UV light absorbent prevents film degradation.

The transparent synthetic resin film 13p is preferably formed to meet the JIS standard for adhesive films for glazings (A5759).

The photovoltaic module 12 will be further described in embodiment 6.

### Embodiment 2

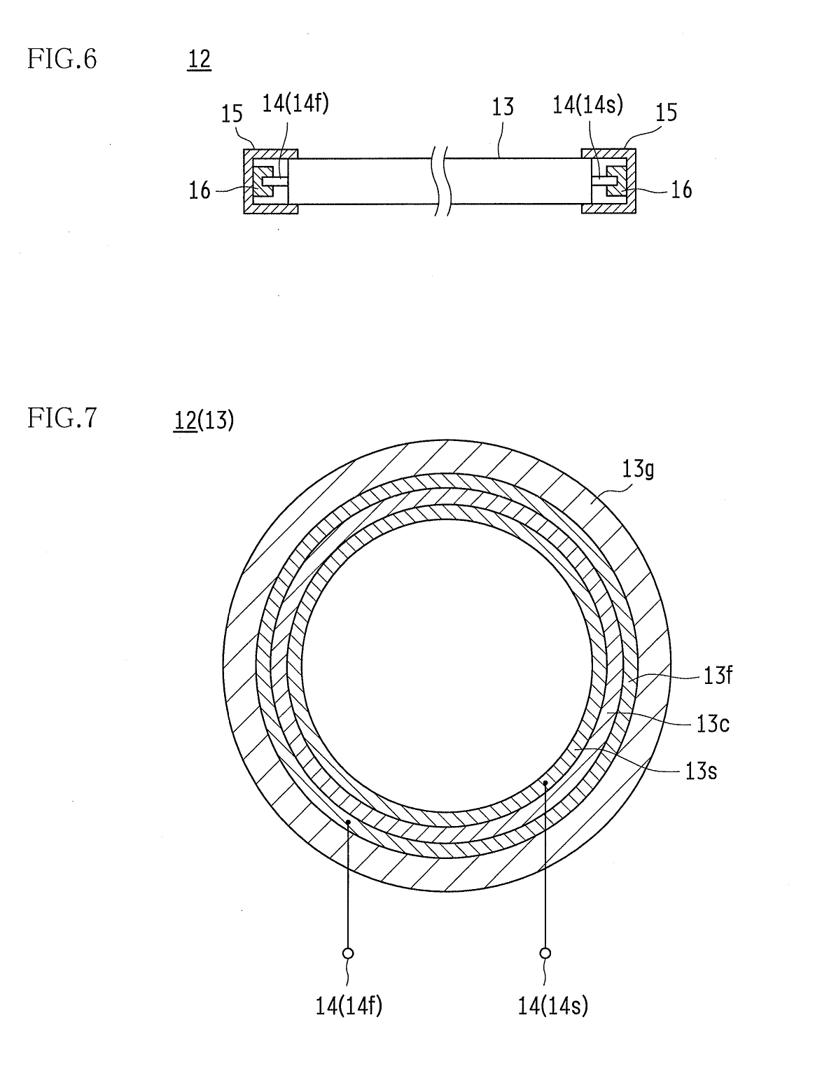

Referring to FIGS. 2A to 2C, a photovoltaic system in accordance with the present embodiment will be described. The present embodiment will not depict any specific structure of the photovoltaic module 12 (the photovoltaic module 22), and its details will be given later in relation to FIGS. 6 and 7. However, since the photovoltaic module 12 in accordance with embodiment 1 is applicable as is, the same reference signs and numerals will be used.

FIG. 2A is an exploded perspective view of a first group 11 of photovoltaic modules and a second group 21 of photovoltaic modules which together constitute a photovoltaic system 1 in accordance with embodiment 2 of the present invention, with the first and second groups being shown detached from each other.

FIG. 2B is a side view of the photovoltaic system 1 shown in FIG. 2A as viewed from the lengthwise direction (arrangement direction Df) of the first group 11 of photovoltaic modules (photovoltaic modules 12).

FIG. 2C is a plan view of the photovoltaic system 1 shown in FIG. 2B as viewed from an illumination light LS side.

The photovoltaic system 1 in accordance with the present embodiment includes a plurality of photovoltaic modules 12 with a bar-like external shape (a plurality of photovoltaic modules 22 with a bar-like external shape). The photovoltaic system 1 includes the first group 11 of photovoltaic modules 12 which are arranged two-dimensionally with intervals therebetween, the second group 21 of photovoltaic modules 22 which are arranged two-dimensionally with intervals therebetween, first holders 15 for holding the first group 11 of photovoltaic modules, and second holders 25 for holding the second group 21 of photovoltaic modules. The first group 11 of photovoltaic modules is disposed on top of, and parallel to, the second group 21 of photovoltaic modules.

According to the photovoltaic system 1 in accordance with the present embodiment, a plurality of groups of two-dimensionally arranged photovoltaic modules (e.g., the first group 11 of photovoltaic modules and the second group 21 of photovoltaic modules) are disposed parallel to each other with one on top of the other. If the first group 11 of photovoltaic modules is disposed on a side illuminated by the illumination light LS, since the second group 21 of photovoltaic modules disposed on a non-illumination light side of the first group 11 of photovoltaic modules acts as a reflection member which reflects light toward the first group 11 of photovoltaic modules and produces reflection (scattered light) toward the non-illumination light side of the first group 11 of photovoltaic modules, the power generation capability per unit area of the first group 11 of photovoltaic modules is improved.

Although the photovoltaic modules 12 and the photovoltaic modules 22 are given different reference numerals for convenience of description, they are identical elements (photovoltaic modules) of the photovoltaic system 1 (the first group 11 of photovoltaic modules and the second group 21 of photovoltaic modules). The “photovoltaic modules” in the photovoltaic system 1 refers to both the photovoltaic modules 12 and the photovoltaic modules 22.

In the first group 11 of photovoltaic modules, the photovoltaic modules 12 are arranged two-dimensionally and preferably in a plane. However, the arrangement is by no means limited to this. Alternatively, the photovoltaic modules 12 may be arranged in a curved surface. Likewise, in the second group 21 of photovoltaic modules, the photovoltaic modules 22 are arranged two-dimensionally and preferably in a plane. However, the arrangement is by no means limited to this. Alternatively, the photovoltaic modules 22 may be arranged in a curved surface.

Both the photovoltaic modules 12 and the photovoltaic modules 22 have a bar-like external shape so that they can receive a photovoltaic output at their ends. The photovoltaic modules 12 (photovoltaic modules 22) will be further detailed in embodiment 6 (FIGS. 6 and 7).

The photovoltaic system 1 (the first group 11 of photovoltaic modules and the second group 21 of photovoltaic modules) is elevated vertically to a height above an installation surface RF by an installation member 40. If the installation surface RF is a deck roof, and the photovoltaic system 1 is installed outdoors, the illumination light LS is sunlight and solar electric generation is possible.

Since the photovoltaic modules 12 and the photovoltaic modules 22 are shaped like a bar, even if the illumination light LS is sunlight and moves (changes its direction) with time along the outer circumference of the bar, the light receiving condition remains almost unchanged. That stable light receiving condition enables stable solar electric generation.

In the photovoltaic system 1 in accordance with the present embodiment, the photovoltaic modules 12 in the first group 11 of photovoltaic modules extend in arrangement direction Df (the lengthwise direction of the bar-like external shape), and the photovoltaic modules 22 in the second group 21 of photovoltaic modules extend in arrangement direction Ds (the lengthwise direction of the bar-like external shape). Arrangement direction Df is parallel to arrangement direction Ds (see FIG. 2C).

Therefore, according to the photovoltaic system 1 in accordance with the present embodiment, the photovoltaic modules 22 which constitute the second group 21 of photovoltaic modules are located in the intervals of the photovoltaic modules 12 which constitute the first group 11 of photovoltaic modules if projected onto a plane (e.g., when viewed from the illumination light LS side). The intervals of the photovoltaic modules (those of the photovoltaic modules 12 and those of the photovoltaic modules 22) are efficiently utilized. That allows for installation of more photovoltaic modules per unit area, and hence improves the power generation capability per unit area of the whole set of photovoltaic modules (the photovoltaic modules 12 and the photovoltaic modules 22). In other words, the efficient use of the intervals of the photovoltaic modules 12 and those of the photovoltaic modules 22 improves the power generation efficiency per unit area of the photovoltaic system 1.

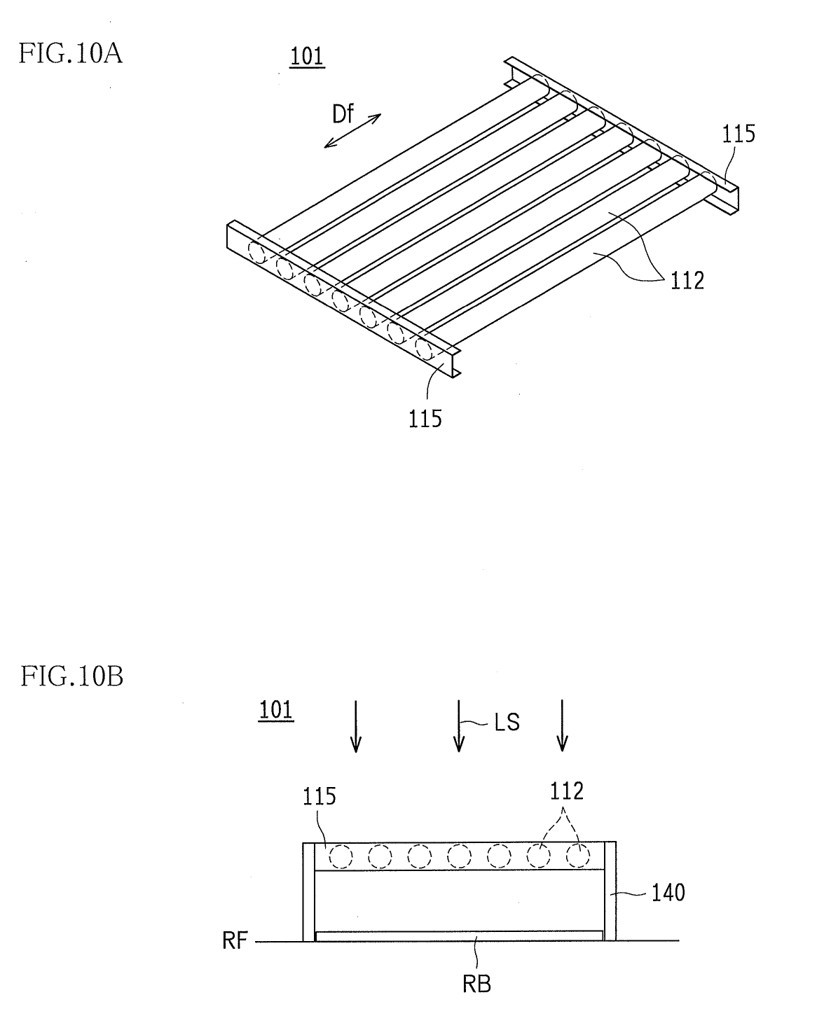

Conventional technology requires the provision of a reflection member RB on the installation surface RF (see FIG. 10B). In contrast, the photovoltaic system 1 in accordance with the present embodiment requires no reflection member RB that is conventionally essential (see FIG. 10B) because the second group 21 of photovoltaic modules forms a reflection surface for the first group 11 of photovoltaic modules. A reflection member (not shown) for the second group 21 of photovoltaic modules may be provided.

The intervals of the two-dimensionally arranged photovoltaic modules 12 and those of the two-dimensionally arranged photovoltaic modules 22 are preferably not so narrow that the photovoltaic modules 12 and the photovoltaic modules 22 can overlap when the first group 11 of photovoltaic modules is disposed on top of the second group 21 of photovoltaic modules (see FIG. 2C).

The intervals of the photovoltaic modules 12 and those of the photovoltaic modules 22 are preferably all equal. The same interval is preferably repeated for all the photovoltaic modules 12 and the photovoltaic modules 22.

The non-overlapping disposition of the photovoltaic modules 12 and the photovoltaic modules 22 maximizes illumination efficiency (area usage efficiency) when the illumination light LS illuminates from the front (perpendicularly to the top face (plane) of the photovoltaic system 1). The provision of the intervals between the photovoltaic modules 12 in the first group 11 of photovoltaic modules increases the illumination light LS reaching the second group 21 of photovoltaic modules. That also improves the power generation capability per unit area.

On the other hand, if the intervals of the photovoltaic modules 12 and the photovoltaic modules 22 are too wide, the first group 11 of photovoltaic modules (the second group 21 of photovoltaic modules) requires a greater footprint. Thus, the power generation capability per unit area is reduced. For these reasons, it is preferable if the intervals are specified properly according to the needs and conditions of the place where the photovoltaic system 1 is installed.

In the photovoltaic system 1, the shape of the two-dimensional arrangement (two-dimensional shape) of the photovoltaic modules 12 in the first group 11 of photovoltaic modules and the shape of the two-dimensional arrangement (two-dimensional shape) of the photovoltaic modules 22 in the second group 21 of photovoltaic modules are preferably identical.

In the photovoltaic system 1 in accordance with the present embodiment, since the shape of the two-dimensional arrangement of the photovoltaic modules 12 in the first group 11 of photovoltaic modules and the shape of the two-dimensional arrangement of the photovoltaic modules 22 in the second group 21 of photovoltaic modules are identical, the groups of photovoltaic modules (the first group 11 of photovoltaic modules and the second group 21 of photovoltaic modules) wherein the first group 11 of photovoltaic modules and the second group 21 of photovoltaic modules have the same two-dimensional shape and overlap are easy to assemble and easy to install.

The shape of the two-dimensional arrangement (two-dimensional shape) of the photovoltaic modules 12 in the first group 11 of photovoltaic modules and the shape of the two-dimensional arrangement (two-dimensional shape) of the photovoltaic modules 22 in the second group 21 of photovoltaic modules may be specified as a shape (peripheral shape) so as to include the first holders 15 and the second holders 25.

If the first group 11 of photovoltaic modules (photovoltaic modules 12) and the second group 21 of photovoltaic modules (photovoltaic modules 22) contain the same number of photovoltaic modules (the same two-dimensional arrangement and the same two-dimensional shape), the photovoltaic modules 12 and the photovoltaic modules 22 are preferably disposed so that they do no overlap when the first group 11 of photovoltaic modules is disposed on top of the second group 21 of photovoltaic modules.

If the first holders 15 holding the photovoltaic modules 12 (the first group 11 of photovoltaic modules) have the same arrangement as the second holders 25 holding the photovoltaic modules 22 (the second group 21 of photovoltaic modules), and the first holders 15 are disposed on top of the second holders 25, the photovoltaic modules 12 are disposed as such on top of the photovoltaic modules 22. Accordingly, either the first group 11 or the second group 21 (e.g., the first group 11 of photovoltaic modules) may be a mirror image of the other (the second group 21 of photovoltaic modules) (see FIGS. 2B and 2C) so that the photovoltaic modules 12 (the first group 11 of photovoltaic modules) and the photovoltaic modules 22 (the second group 21 of photovoltaic modules) do not overlap in the plan view when viewed from the illumination light LS direction even if the photovoltaic modules 12 and 22 have the same two-dimensional arrangement (the same two-dimensional shape).

The number of the photovoltaic modules 12 in the first group 11 of photovoltaic modules may differ from the number of the photovoltaic modules 22 in the second group 21 of photovoltaic modules.

As mentioned above, the photovoltaic system 1 in accordance with the present embodiment includes at least two faces, one formed by the first group 11 of photovoltaic modules 12 and the other by the second group 21 of photovoltaic modules 22, the two faces being separated vertically and mutually parallel.

Alternatively, if the photovoltaic modules 12 in accordance with embodiment 1 are used, the photovoltaic system 1 in accordance with the present embodiment may include a single face formed by the vertically arranged, first group 11 of the photovoltaic modules 12.

The photovoltaic system 1 in accordance with the present embodiment is preferably a photovoltaic system 1 including a plurality of photovoltaic modules 12 with a bar-like external shape, the system including: a first group 11 of photovoltaic modules (a group of photovoltaic modules) in which the plurality of photovoltaic modules 12 are arranged two-dimensionally with intervals therebetween; and first holders 15 (holders) for holding the first group 11 of photovoltaic modules, wherein the photovoltaic modules 12 are those in accordance with embodiment 1.

Hence, the photovoltaic system 1 in accordance with the present embodiment includes: a first group 11 of photovoltaic modules (a group of photovoltaic modules) in which the photovoltaic modules 12 in accordance with embodiment 1 are arranged two-dimensionally with intervals therebetween; and first holders 15 (holders) for holding the first group 11 of photovoltaic modules. The photovoltaic system 1 is therefore very safe and efficient.

### Embodiment 3

Referring to FIGS. 3A to 3C, a photovoltaic system in accordance with the present embodiment will be described.

A photovoltaic system 1 in accordance with the present embodiment has a similar basic configuration to that of the photovoltaic system 1 in accordance with embodiment 2. Hence, the same reference numerals will be used, and the description will focus on major differences. The photovoltaic modules 12 in accordance with embodiment 1 are used as such in the present embodiment as in embodiment 2.

FIG. 3A is an exploded perspective view of a first group 11 of photovoltaic modules and a second group 21 of photovoltaic modules which together constitute a photovoltaic system 1 in accordance with embodiment 3 of the present invention, with the first and second groups 11 and 21 being shown detached from each other.

FIG. 3B is a side view of the photovoltaic system 1 shown in FIG. 3A as viewed from the lengthwise direction (arrangement direction Df) of the first group 11 of photovoltaic modules 12.

FIG. 3C is a plan view of the photovoltaic system 1 shown in FIG. 3B as viewed from an illumination light LS side.

The photovoltaic system 1 in accordance with the present embodiment includes a plurality of photovoltaic modules 12 with a bar-like external shape and a plurality of photovoltaic modules 22 with a bar-like external shape. The photovoltaic system 1 includes the first group 11 of photovoltaic modules 12 which are arranged two-dimensionally with intervals therebetween, the second group 21 of photovoltaic modules 22 which are arranged two-dimensionally with intervals therebetween, first holders 15 for holding the first group 11 of photovoltaic modules, and second holders 25 for holding the second group 21 of photovoltaic modules. The first group 11 of photovoltaic modules is disposed on top of, and parallel to, the second group 21 of photovoltaic modules.

According to the photovoltaic system 1 in accordance with the present embodiment, a plurality of groups of photovoltaic modules (e.g., the first group 11 of photovoltaic modules and the second group 21 of photovoltaic modules) are disposed parallel to each other with one on top of the other. If the first group 11 of photovoltaic modules is disposed on a side illuminated by the illumination light LS, since the second group 21 of photovoltaic modules disposed on a non-illumination light side of the first group 11 of photovoltaic modules acts as a reflection member which reflects light toward the first group 11 of photovoltaic modules and produces reflection (scattered light) toward the non-illumination light side of the first group 11 of photovoltaic modules, the power generation capability per unit area of the first group 11 of photovoltaic modules is improved.

In the photovoltaic system 1 in accordance with the present embodiment, the photovoltaic modules 12 in the first group 11 of photovoltaic modules extend in arrangement direction Df (the lengthwise direction of the bar-like external shape), and the photovoltaic modules 22 in the second group 21 of photovoltaic modules extend in arrangement direction Ds (the lengthwise direction of the bar-like external shape). Arrangement direction Df intersects arrangement direction Ds (see FIG. 3C).

Therefore, according to the photovoltaic system 1 in accordance with the present embodiment, the photovoltaic modules 22 which constitute the second group 21 of photovoltaic modules extend in arrangement direction Ds which intersects arrangement direction Df in which the photovoltaic modules 12 which constitute the first group 11 of photovoltaic modules extend when projected onto a plane (e.g., when viewed from the illumination light LS side). Therefore, the photovoltaic system 1 further reduces adverse effect of the ever-changing illumination light LS (such as, sunlight) to improve power generation efficiency.

In the photovoltaic system 1, the shape of the two-dimensional arrangement (two-dimensional shape) of the photovoltaic modules 12 in the first group 11 of photovoltaic modules and the shape of the two-dimensional arrangement (two-dimensional shape) of the photovoltaic modules 22 in the second group 21 of photovoltaic modules are preferably identical.

In the photovoltaic system 1 in accordance with the present embodiment, since the shape of the two-dimensional arrangement of the photovoltaic modules 12 in the first group 11 of photovoltaic modules and the shape of the two-dimensional arrangement of the photovoltaic modules 22 in the second group 21 of photovoltaic modules are identical, the groups of photovoltaic modules (the first group 11 of photovoltaic modules and the second group 21 of photovoltaic modules) wherein the first group 11 of photovoltaic modules and the second group 21 of photovoltaic modules have the same two-dimensional shape and overlap are easy to assemble and easy to install.

The shape of the two-dimensional arrangement (two-dimensional shape) of the photovoltaic modules 12 in the first group 11 of photovoltaic modules and the shape of the two-dimensional arrangement (two-dimensional shape) of the photovoltaic modules 22 in the second group 21 of photovoltaic modules may be specified as a shape (peripheral shape) so as to include the first holders 15 and the second holders 25.

Since the peripheral shapes which include the first holders 15 and the second holders 25 are identical, the first group 11 including the first holders 15 and the second group 21 including the second holders 25 can overlap by rotating the first group 11 of photovoltaic modules by 90° with respect to the second group 21 of photovoltaic modules or conversely rotating the second group 21 of photovoltaic modules by 90° with respect to the first group 11 of photovoltaic modules.

Therefore, the first group 11 of photovoltaic modules with the first holders 15 being attached thereto and the second group 21 of photovoltaic modules with the second holders 25 being attached thereto preferably have a square shape.

Unlike embodiment 2, arrangement direction Df in which the photovoltaic modules 12 extend intersects arrangement direction Ds in which the photovoltaic modules 22 extend in the present embodiment. When the photovoltaic modules 12 and the photovoltaic modules 22 have the same two-dimensional arrangement, the arrangement of the first holders 15 and the arrangement of the second holders 25 have different shapes if the two-dimensional shapes are rectangular, and the first group 11 of photovoltaic modules with the first holders 15 being attached thereto is disposed on top of the second group 21 of photovoltaic modules with the second holders 25 being attached thereto. Therefore, the reflection from the second group 21 of photovoltaic modules disposed below may not reach the first group 11 of photovoltaic modules in sufficient quantity.

Therefore, the two-dimensional shape of the first group 11 of photovoltaic modules and that of the second group 21 of photovoltaic modules preferably match, so that the reflection from the second group 21 of photovoltaic modules disposed below can reach the first group 11 of photovoltaic modules in sufficient quantity. Specifically, the two-dimensional shape of the photovoltaic modules 12 together with the first holders 15 supporting the photovoltaic modules 12 and the two-dimensional shape of the photovoltaic modules 22 together with the second holders 25 supporting the photovoltaic modules 22 preferably have equal lengths and widths to form a square, so that a square (see FIG. 3C) is formed when the photovoltaic modules 12 (the first group 11 of photovoltaic modules) are disposed on top of, and so as to intersect, the photovoltaic modules 22 (the second group 21 of photovoltaic modules).

If the first group 11 of photovoltaic modules and the second group 21 of photovoltaic modules are to form a square external shape state (outer circumference state in the plan view) when the group 11 is disposed on top of the group 21, the first group 11 of photovoltaic modules and the second group 21 of photovoltaic modules should be prepared so as to have substantially identical shapes (lengths and widths) (squares of substantially identical size) in the plan view and disposed with one on top of the other with 90° different orientations. Hence, the photovoltaic system 1 improves productivity and is easy to install.

The first group 11 of photovoltaic modules and the second group 21 of photovoltaic modules are by no means limited to square shapes and may be rectangular.

### Embodiment 4

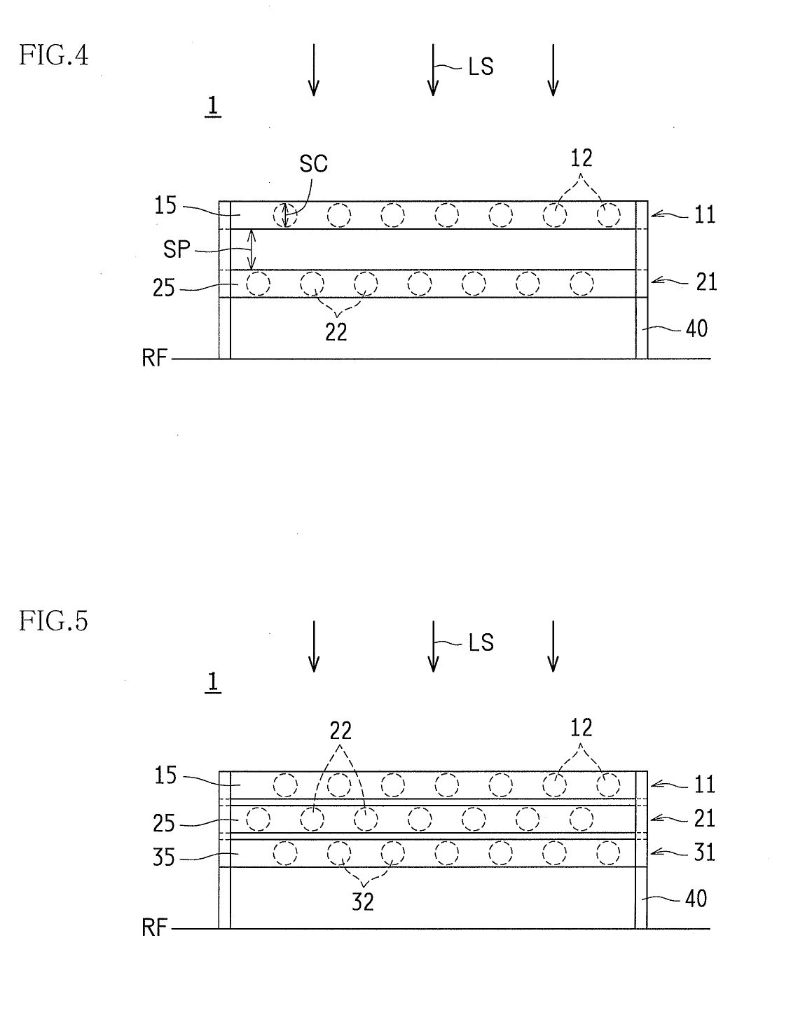

Referring to FIG. 4, a photovoltaic system in accordance with the present embodiment will be described.

A photovoltaic system 1 in accordance with the present embodiment has a similar basic configuration to that of the photovoltaic system 1 in accordance with embodiments 2 and 3. Hence, the same reference numerals will be used, and the description will focus on major differences. The photovoltaic system 1 in accordance with the present embodiment is applicable to embodiments 2 and 3. In addition, the photovoltaic modules 12 in accordance with embodiment 1 are applicable to the present embodiment as well as to embodiments 2 and 3.

FIG. 4 is a side view of the photovoltaic system 1 in accordance with embodiment 4 of the present invention, showing a gap SP between a first group 11 of photovoltaic modules and a second group 21 of photovoltaic modules which together constitute the photovoltaic system 1.

In the photovoltaic system 1 in accordance with the present embodiment, the gap SP between the first group 11 of photovoltaic modules and the second group 21 of photovoltaic modules is preferably specified to be greater than the size SC of an external shape in the direction in which the first group 11 of photovoltaic modules is disposed on top of the second group 21 of photovoltaic modules (the size of the external shape in the direction which intersects the lengthwise direction of the photovoltaic modules 12, the size of the external shape in the direction which intersects the lengthwise direction of the photovoltaic modules 22).

The photovoltaic system 1 in accordance with the present embodiment has a sufficient gap SP between the first group 11 of photovoltaic modules and the second group 21 of photovoltaic modules. The structure allows for an increased amount of light being uniformly reflected (scattered) between the first group 11 of photovoltaic modules and the second group 21 of photovoltaic modules. Hence, the power generation capability per unit area of the first group 11 of photovoltaic modules and the second group 21 of photovoltaic modules is surely improved.

The gap SP is provided by inserting proper spacers between first holders 15 and second holders 25.

### Embodiment 5

Referring to FIG. 5, a photovoltaic system in accordance with the present embodiment will be described.

A photovoltaic system 1 in accordance with the present embodiment has a similar basic configuration to that of the photovoltaic system 1 in accordance with embodiments 2 to 4. Hence, the same reference numerals will be used, and the description will focus on major differences. The photovoltaic system 1 in accordance with the present embodiment is also applicable to embodiments 2 to 4. In addition, the photovoltaic modules 12 in accordance with embodiment 1 are applicable to the present embodiment as well as to embodiments 2 to 4.

FIG. 5 is a side view of the photovoltaic system 1 in accordance with embodiment 5 of the present invention, showing relative positions of a first group 11 of photovoltaic modules, a second group 21 of photovoltaic modules, and a third group 31 of photovoltaic modules which together constitute the photovoltaic system 1.

The photovoltaic system 1 in accordance with the present embodiment is by no means limited to the two planes formed by the first group 11 of photovoltaic modules and the second group 21 of photovoltaic modules (a plane is formed by the photovoltaic modules 12, and another plane is formed by the photovoltaic modules 22). The photovoltaic system 1 may have a third layer.

Specifically, the photovoltaic system 1 in accordance with the present embodiment includes the third group 31 of photovoltaic modules as well as the first group 11 of photovoltaic modules and the second group 21 of photovoltaic modules. The third group 31 of photovoltaic modules includes photovoltaic modules 32 which are arranged two-dimensionally with intervals therebetween. The third group 31 of photovoltaic modules is held by third holders 35.

In other words, the third group 31 of photovoltaic modules is structured similarly to the first group 11 of photovoltaic modules and the second group 21 of photovoltaic modules. The photovoltaic modules 32 are arranged similarly to the photovoltaic modules 12 and the photovoltaic modules 22.

More layers may be provided by increasing the gaps between the first group 11 of photovoltaic modules, the second group 21 of photovoltaic modules, and the third group 31 of photovoltaic modules. In addition, if the first group 11 of photovoltaic modules, the second group 21 of photovoltaic modules, and the third group 31 of photovoltaic modules are to be configured to form respective curved surfaces, it is more effective.

### Embodiment 6

Referring to FIGS. 6 and 7, the following will describe, as embodiment 6, first holders 15 which hold photovoltaic modules 12 with a bar-like external shape (photovoltaic modules as elements for the photovoltaic system 1) and photovoltaic modules 12 (a first group 11 of photovoltaic modules). The photovoltaic modules 12 and the first holders 15 are applicable as such to the photovoltaic system 1 in accordance with embodiments 2 to 5. Detailed description of the photovoltaic system 1 may be omitted where appropriate.

Photovoltaic modules 22, second holders 25 holding the photovoltaic modules 22 (embodiments 2 to 4), photovoltaic modules 32, and third holders 35 holding and the photovoltaic modules 32 (embodiment 5) are structured similarly to the photovoltaic modules 12 and the first holders 15. The description will therefore focus on the photovoltaic modules 12 and the first holders 15.

FIG. 6 is a schematic cross-sectional partial view of the first holders 15 connecting the photovoltaic modules 12 in accordance with embodiment 6 of the present invention.

FIG. 7 is a schematic cross-sectional view of an internal structure of the photovoltaic modules 12 shown in FIG. 6.

The photovoltaic module 12 in accordance with the present embodiment has a bar-like external shape and includes a photovoltaic element (e.g., solar cell element) provided inside the bar-shaped exterior. Specifically, the photovoltaic module 12 includes a main body section 13 and output terminals 14 provided on the ends of the main body section 13. The output terminals 14 consists of an output terminal 14f corresponding to an outer electrode 13f (FIG. 7) and an output terminal 14s corresponding to an inner electrode 13s (FIG. 7).

The output terminal 14f (one of the output terminals 14) is connected to a wire 16 formed on the first holder 15 holding one of the ends of a photovoltaic module 12. The output terminal 14s (the other one of the output terminals 14) is connected to a wire 16 formed on the first holder 15 holding the other end of the photovoltaic module 12. In this connection mode where the outer electrodes 13f are provided in one of the first holders 15 and the inner electrodes 13s are provided in the other one of the first holders 15, the photovoltaic modules 12 are preferably connected in parallel in the first group 11 of photovoltaic modules.

The connection mode of the output terminals 14f and the output terminals 14s is by no means limited to this connection mode. Alternatively, when the output terminals 14f and the output terminals 14s are in a connection mode where an alternate one of the output terminals 14f and 14s is positioned for output to one of the first holders 15 (wires 16), the photovoltaic modules 12 may be connected in series in the first group 11 of photovoltaic modules.

The first holder 15 preferably has an open groove on a face thereof where the photovoltaic modules 12 are positioned and inserted. With such a groove, the first holder 15 is only open on its face facing the photovoltaic modules 12, with the other faces being closed to the outside. The structure allows for stable connection to the photovoltaic modules 12 by eliminating external influence.

The provision of the wires 16 inside the first holder 15 enables the first holder 15 to provide easy access to the solar electric power output of the photovoltaic modules 12 (the first group 11 of photovoltaic modules) as well as to hold the photovoltaic modules 12 (the first group 11 of photovoltaic modules). The provision also enables elimination of external influence and safe output, thereby ensuring weatherability and reliability of the photovoltaic system 1.

The main body section 13 is transparent so that it can admit external illumination light LS (see FIGS. 2B and 3B) and made of, for example, a cylindrical glass tube. The main body section 13 is preferably cylindrical in order to ensure strength and also to allow sufficient illumination light to uniformly illuminate the bar-like interior, in no matter which direction the illumination light LS is traveling. The cylinder has a diameter (outer circumference) of, for example, approximately 20 mm to 40 mm and a length of, for example, approximately 1,000 mm. The cylinder has a sufficient thickness to ensure strength, for example, approximately 1 mm.

The photovoltaic module 12 includes a glass tube 13g constituting the main body section 13, an outer electrode 13f disposed inside the glass tube 13g, a photoelectric conversion layer (photovoltaic layer) 13c disposed inside the outer electrode 13f, and an inner electrode 13s disposed inside the photoelectric conversion layer 13c. A photovoltaic element is formed by the outer electrode 13f, the photoelectric conversion layer 13c, and the inner electrode 13s.

The main body section 13 is by no means limited to a glass tube and may be made of another transparent raw material, for example, an acrylic resin or other plastic, a ceramic, or a like material.

The outer electrode 13f is composed of, for example, ITO (indium tin oxide) or a like transparent material because it needs to allow illumination light to be incident to the internally disposed photoelectric conversion layer 13c. The photoelectric conversion layer 13c is, for example, a compound semiconductor layer and composed of CuInGaSe. The inner electrode 13s is composed of, for example, Mo. This particular structure is known as a CIGS solar cell.

The photovoltaic element in the photovoltaic module 12 is by no means limited to a CIGS solar cell and may be of any type including silicon and compound semiconductor solar cells.

As mentioned above, in the photovoltaic system 1, the photovoltaic module 12 (the photovoltaic module 12 with a bar-like external shape) preferably has a cylindrical external shape. This particular shape gives necessary and sufficient mechanical strength and weatherability to the photovoltaic system 1 in accordance with the present embodiment, thereby enabling outdoor installation for solar electric generation.

So far in the present embodiment, the main body section 13 which defines the external shape of the photovoltaic module 12 has been described as being shaped like a bar and specifically like a (hollow) cylinder (tube). Alternatively, the main body section 13 may be shaped like an elliptic or polygonal cylinder (tube), or the like. In addition, a cylinder (tube) in this context is not necessarily hollow and may be of a solid circular, elliptic, or polygonal column which contains therein an electrode and a photoelectric conversion section.

As mentioned above, the photovoltaic module 12 in accordance with the present embodiment is applied as such to the photovoltaic system 1 in accordance with embodiments 2 to 5 so as to act as a part of the photovoltaic system 1.

Specifically, in the photovoltaic system 1, the first holders 15, the second holders 25, and the third holders 35 include wires (e.g., the wires 16 for the first holders 15) connected to output terminals (e.g., the output terminals 14 of the photovoltaic modules 12) of photovoltaic modules (the photovoltaic modules 12, the photovoltaic modules 22, and the photovoltaic modules 32). Therefore, the photovoltaic system 1 in accordance with the present embodiment can surely collect generated electric power with improved reliability.

Embodiments 2 to 6 in accordance with the present invention have been detailed so far. The present invention is by no means limited to those embodiments and variations, and encompasses in its scope design and other modifications that do not depart from the spirit of the present invention.

In relation to the photovoltaic module 12 in accordance with the present embodiment, the description has not mentioned anything about the transparent synthetic resin film 13p provided on the photovoltaic module 12 in accordance with embodiment 1. However, the transparent synthetic resin film 13p is also applied as such in the present embodiment.

### Embodiment 7

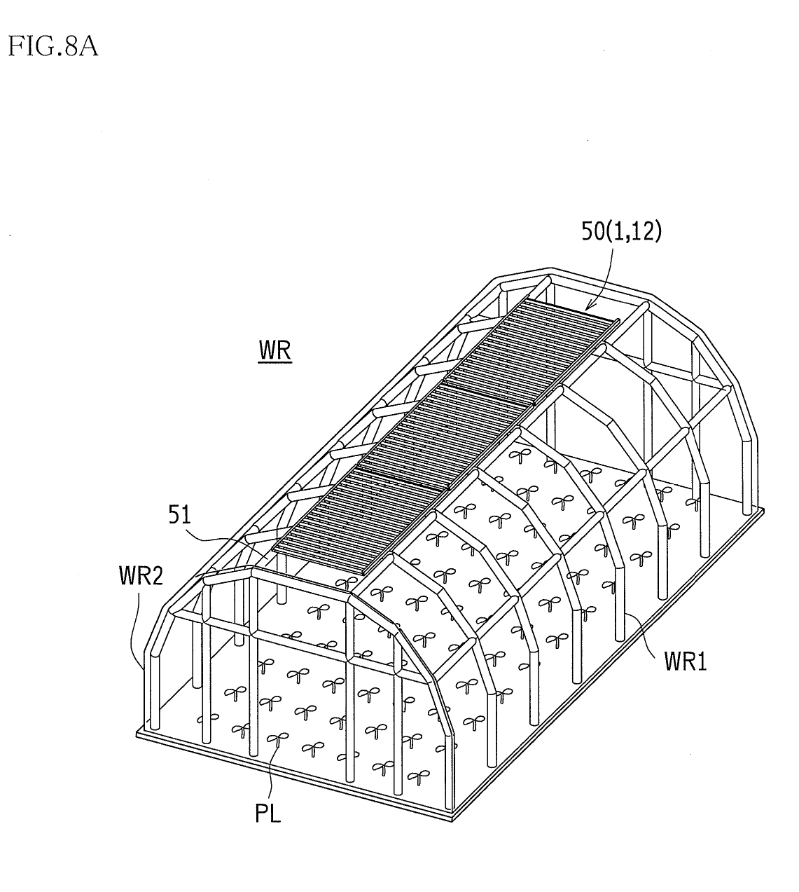

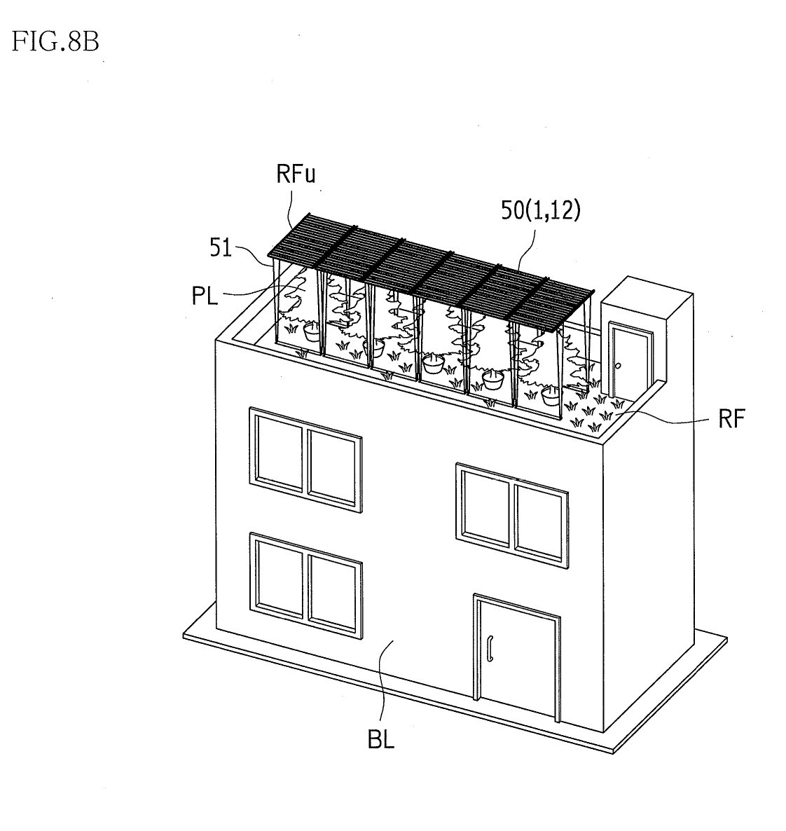

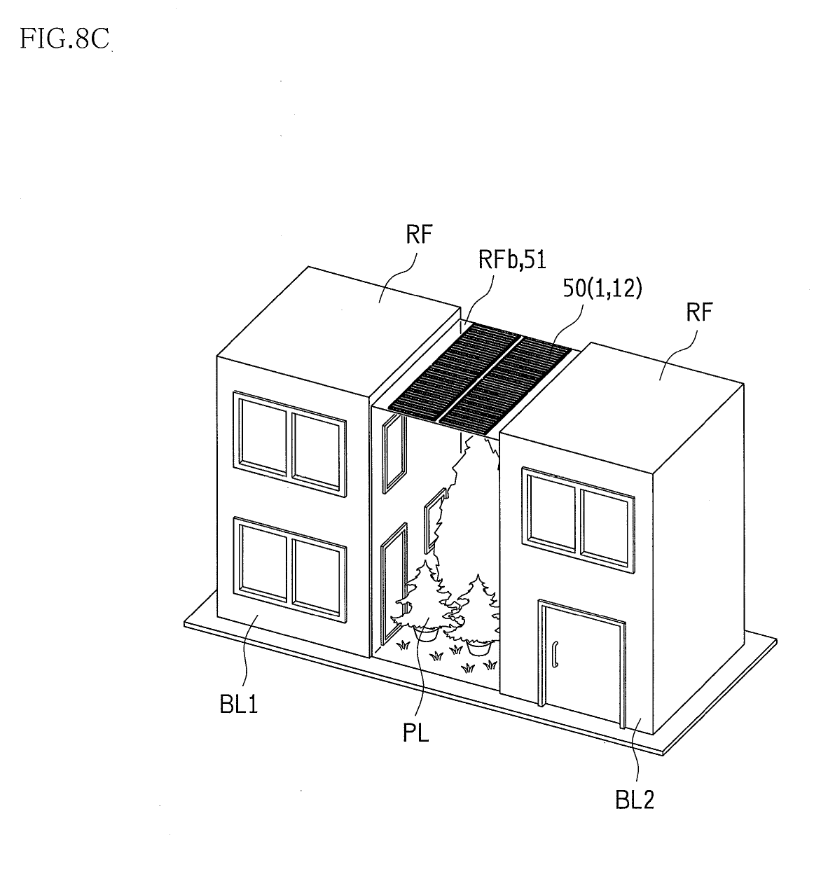

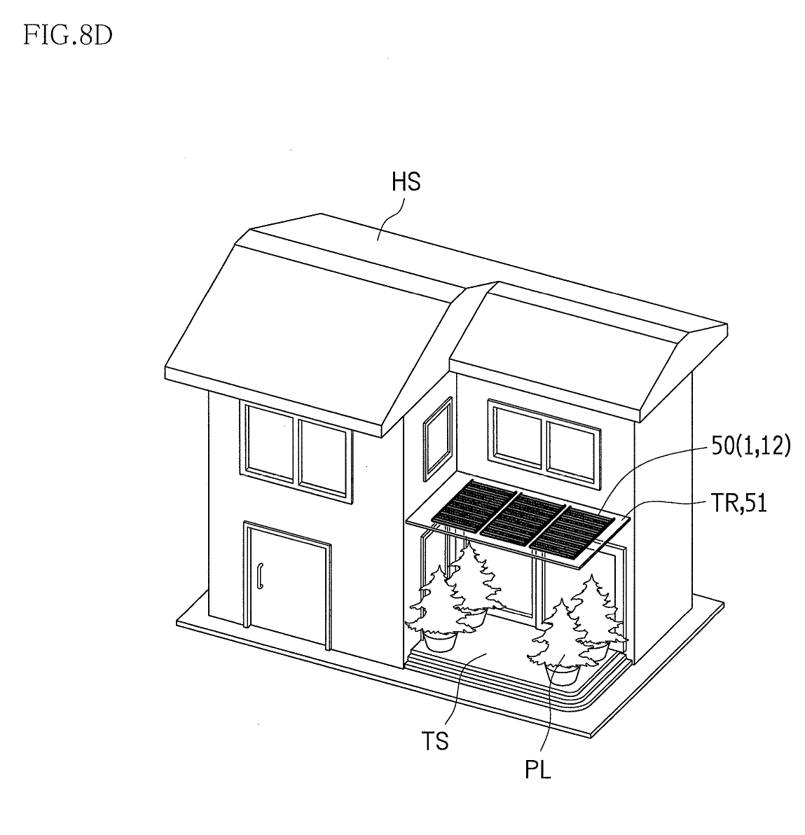

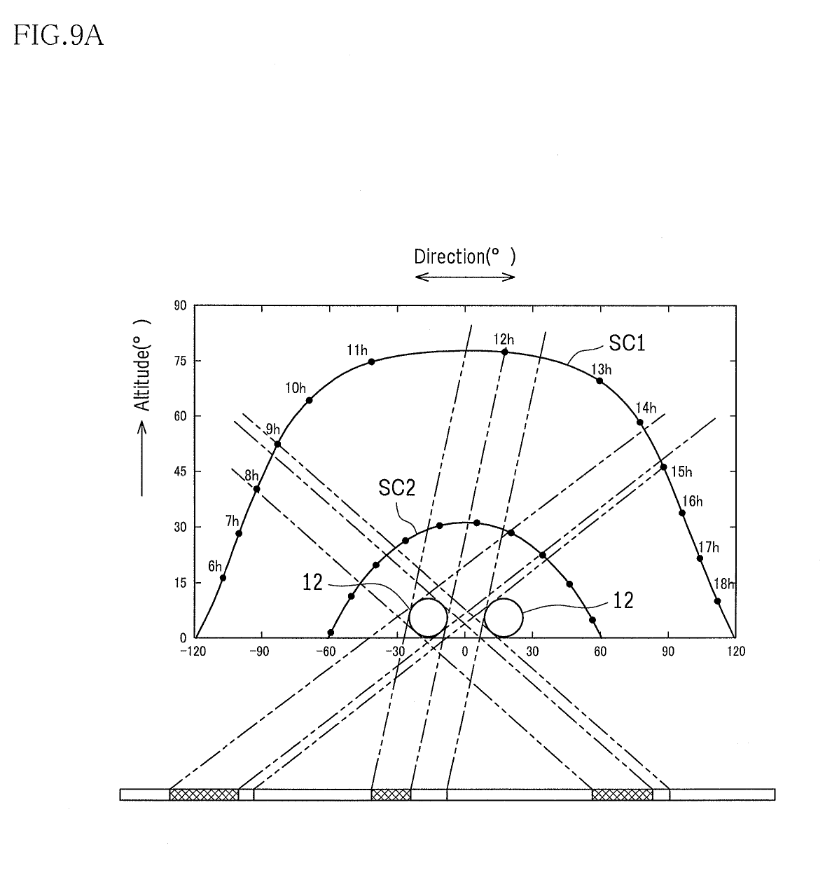

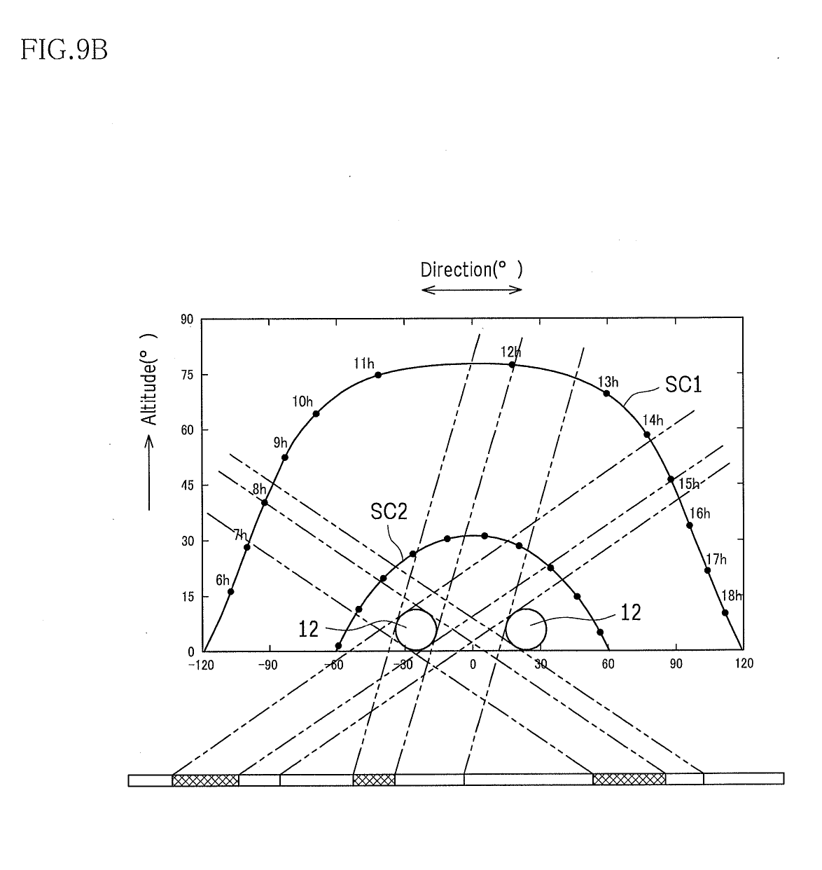

Referring to FIGS. 8A to 9B, a light admitting apparatus 50 in accordance with the present embodiment will be described. The light admitting apparatus 50 is a photovoltaic system 1 including a plurality of photovoltaic modules 12 (see other embodiments) which is applied to an artificial apparatus (a greenhouse WR in FIG. 8A, a top roof RFu disposed on a top RF in FIG. 8B, a building-connecting roof RFb disposed between buildings in FIG. 8C, a terrace roof TR disposed over a terrace in FIG. 8D) so as to reduce for example, sunlight reaching plants PL.

FIG. 8A is a schematic and conceptual oblique view of a light admitting apparatus 50 (example 1) in accordance with embodiment 7 of the present invention.

Plants PL are planted in the greenhouse WR. The greenhouse WR includes a framework WR1 defining an external shape and sheltering surfaces WR2 arranged on the framework WR1 to provide the internal space of the greenhouse WR with shelter from external environment. The sheltering surfaces WR2 are formed of, for example, a transparent film.

The light admitting apparatus 50 (photovoltaic system 1, photovoltaic modules 12) in accordance with example 1 is disposed on the top face of the greenhouse WR via a support section 51. Therefore, external light (e.g., sunlight) is admitted to the space in the greenhouse WR. Light admittance will be described in relation to FIGS. 9A and 9B (and so it will for example 2 to example 4 below).

FIG. 8B is a schematic and conceptual oblique view of a light admitting apparatus 50 (example 2) in accordance with embodiment 7 of the present invention.

A plant PL, as an example, is disposed on a top RF of a building BL. The light admitting apparatus 50 (the photovoltaic system 1, the photovoltaic modules 12) is provided via the support section 51 to shield the plant PL. The light admitting apparatus 50 forms the top roof RFu on the top face of the support section 51. Therefore, the light admitting apparatus 50 admits light for the plant PL and acts as a light admitting apparatus.

FIG. 8C is a schematic and conceptual oblique view of a light admitting apparatus 50 (example 3) in accordance with embodiment 7 of the present invention.

A space is provided between a building 1 and a building 2, and a building-connecting roof RFb is provided between a top RF of the building 1 and a top RF of the building 2. A plant PL, as an example, is planted in the ground under the building-connecting roof RFb. The building-connecting roof RFb is disposed over the plant PL and may therefore shade the plant PL. The building-connecting roof RFb acting as a support section 51, however, is provided with the light admitting apparatus 50 (the photovoltaic system 1, the photovoltaic modules 12) which acts as a light admitting apparatus for the plant PL.

FIG. 8D is a schematic and conceptual oblique view of a light admitting apparatus 50 (example 4) in accordance with embodiment 7 of the present invention.

A terrace roof TR is provided over a terrace TS of a house HS. A plant PL, as an example, is planted in the terrace TS under the terrace roof TR. The terrace roof TR acting as a support section 51 is provided with the light admitting apparatus 50 (the photovoltaic system 1, the photovoltaic modules 12) which acts as a light admitting apparatus for the plant PL.

As illustrated in FIGS. 8A to 8D above, the light admitting apparatus 50 in accordance with the present embodiment includes the photovoltaic modules 12 with a bar-like external shape, the apparatus 50 including: the photovoltaic system 1 including a plurality of the photovoltaic modules 12; and a support section 51 for supporting the photovoltaic system 1, wherein the photovoltaic modules 12 are the photovoltaic modules in accordance with embodiments 1 to 6, and the photovoltaic system 1 is the photovoltaic system 1 in accordance with embodiments 2 to 6.

Therefore, the light admitting apparatus 50 in accordance with the present embodiment both generates electricity from solar energy and admits light, which adds to the usage of the photovoltaic modules 12. Next, in reference to FIGS. 9A and 9B, the following will describe light admittance being controlled through the arrangement of the photovoltaic modules 12.

FIG. 9A is a graph representing how light admittance changes in relation to the path of the sun (altitude and direction) and the arrangement of the photovoltaic modules 12 ((module diameter):(module interval)=1:1).

The graph shows the sun's direction along its path (from −120° to the east through 0° (culmination) to −120° to the west) on the horizontal axis and the sun's altitude (from 0° to 90°) on the vertical axis. The curved line SC1 represents the path of the sun on the summer solstice. The curved line SC2 represents the path of the sun on the winter solstice. The bar parallel to the horizontal axis represents a relative ratio of admission area and shield area. The graph represents data for Japan (Tokyo). Time (6 h to 18 h) is plotted on the curved lines. The same explanation applies to FIG. 9B.

FIG. 9A shows a relationship, for the sun's path, between the shield area where sunlight is blocked and the admission area where sunlight is admitted when the photovoltaic modules 12 are arranged so that (module diameter):(module interval)=1:1.

On the summer solstice, the admission area is 40%, and the shield area is 60% at noon (12 h); the admission area is 10%, and the shield area is 90% at 9 h; and the admission area is 10%, and the shield area is 90% at 15 h. In other words, the light admittance is 40% at noon and 10% at 9 h and 15 h.

FIG. 9B is a graph representing how light admittance changes in relation to the path of the sun (altitude and direction) and the arrangement of the photovoltaic modules 12 ((module diameter): (module interval)=1:1.6).

FIG. 9B shows a relationship, for the sun's path, between the shield area where sunlight is blocked and the admission area where sunlight is admitted when the photovoltaic modules 12 is arranged so that (module diameter):(module interval)=1:1.6.

On the summer solstice, the admission area is 60%, and the shield area is 40% at noon (12 h); the admission area is 30%, and the shield area is 70% at 9 h; and the admission area is 30%, and the shield area is 70% at 15 h. In other words, the light admittance is 60% at noon and 30% at 9 h and 15 h.

Therefore, as shown in FIGS. 9A and 9B, the ratio of the admission area and the shield area can be changed by modifying the arrangement of the photovoltaic modules 12 (proportion of module interval to module diameter). In other words, the light admittance (Admission Area/(Admission Area+Shield Area)) can be changed.

A typical flat installation type of solar cell module cannot be configured as a light admitting apparatus for some reasons including the solar cells being fixed in a plane in the solar cell module and light being blocked by the surface on which the solar cell modules are disposed. In contrast, according to the photovoltaic modules 12 in accordance with the present embodiment, the photovoltaic system 1 is configured which has intervals between the photovoltaic modules 12, and the intervals can be used to configure the light admitting apparatus 50.

The arrangement of the photovoltaic modules 12 may be modified as needed by, for example, altering the intervals of the photovoltaic modules 12 or altering the relative positions of the first holders 15 holding the photovoltaic modules 12, the second holders 25, and the third holders 35.

The light admitting apparatus 50 is capable of efficiently admitting sunlight for plants during the course of the day if the intervals of the photovoltaic modules 12 are adjusted according to the sun's path (direction).

In the spring and autumn when demand on the photovoltaic system 1 for power generation is relatively low, the intervals of the photovoltaic modules 12 in the photovoltaic system 1 may be adjusted so that more light is admitted for plants.

Alternatively, the electric power generated during the daytime by the photovoltaic system 1 (photovoltaic modules 12) in the light admitting apparatus 50 may be stored in a rechargeable battery where possible so that the plants PL can be illuminated as needed at night.

### INDUSTRIAL APPLICABILITY

The present invention (photovoltaic module, photovoltaic system, light admitting apparatus) may be used for a photovoltaic module, a photovoltaic system, and a light admitting apparatus, for example, for outdoor installation to convert sunlight to electricity. The present invention is effectively applicable for electric power generation from a clean energy source.

### REFERENCE SIGNS LIST

1 Photovoltaic System
11 First Group of Photovoltaic Modules
12 Photovoltaic Module
13 Main Body Section
13p Transparent Synthetic Resin Film
14 Output Terminal
15 First Holder
16 Wire
21 Second Group of Photovoltaic Modules
22 Photovoltaic Module
25 Second Holder
31 Third Group of Photovoltaic Modules
32 Photovoltaic Module
35 Third Holder
40 Installation Member
50 Light Admitting Apparatus
51 Support Section
Df Arrangement Direction
Ds Arrangement Direction
LS Illumination Light
RF Installation Surface
SC Size
SP Gap

1. A photovoltaic module with a bar-like external shape, comprising:
a main body section forming the external shape;
a photovoltaic element provided inside the main body section; and
output terminals provided on respective ends of the main body section for output of electric power generated by the photovoltaic element,
wherein the main body section is covered with a transparent synthetic resin film.

2. A photovoltaic system, comprising:
a first group of photovoltaic modules prepared by two-dimensionally arranging the photovoltaic modules as set forth in claim 1 with intervals therebetween; and
first holders for holding the first group of photovoltaic modules.

3. A light admitting apparatus, comprising:
a photovoltaic system as set forth in claim 2; and
a support section for supporting the photovoltaic system.
